(19) United States
(12) Patent Application Publication
(10) Pub. No.: US 2002/0085360 A1
(43) Pub. Date: Jul. 4, 2002

(54) Layered circuit boards and methods of production thereof

(76) Inventor: Yutaka Doi, Minnetonka, MN (US)

Correspondence Address: Honeywell International Inc., Law Dept. AB2, P.O. Box 2245, 101 Columbia Road, Morristown, NJ, 07962, US

(21) Appl. No.: 09/752,660

(22) Filed: Dec. 28, 2000

(51) Int. Cl. H05K 1/16; H05K 1/03; H05K 1/09

(52) U.S. Cl. 361/782; 361/793; 29/846; 29/832

(57) ABSTRACT

Compositions and methods are provided whereby electronic components may be produced that comprise a) a substrate layer; b) an insulator layer coupled to the substrate layer, wherein the insulator layer comprises at least two different kinds of embedded passive components; and c) at least one additional layer coupled to the insulator layer. A preferred method comprises a) imaging an insulator layer to create a first pattern on the insulator layer; b) etching the first pattern on the insulator layer to create a first compartment in the insulator layer; c) filling the first compartment with a first material to form a first passive component; d) imaging the insulator layer to create a second pattern on the insulator layer; e) etching the second pattern on the insulator layer to create a second compartment in the insulator layer; and f) filling the second compartment with a second material to form a second passive component.

### FIELD OF THE INVENTION

The field of the invention is electronic components.

### BACKGROUND OF THE INVENTION

Electronic components are used in ever increasing numbers of consumer and commercial electronic products. Examples of some of these consumer and commercial products are televisions, computers, cell phones, pagers, a palm-type, personal organizer, portable radios, car stereos, or remote controls. As the demand for these consumer and commercial electronics increases, there is also a demand for those same products to become smaller and more portable for the consumers and businesses.

As a result of the size decrease in these products, the components that comprise the products must also become smaller. Examples of some of those components that need to be reduced in size or scaled down are printed circuit or wiring boards, resistors, capacitors, wiring, keyboards, touch pads, and chip packaging.

Components, therefore, are being broken down and investigated to determine if there are better building materials, better design strategies and methods that will allow those components to be scaled down to accommodate the demands for smaller electronic components. In layered components, one goal appears to be decreasing the number or the size of the layers. This task can be difficult, however, given that several of the layers and components of the layers should generally be present in order to operate the component.

Thus, there is a continuing need to a) design and produce layered materials that meet customer specifications while minimizing the size and number of layers, and b) develop reliable methods of producing desired layered materials and components comprising those layered materials.

### SUMMARY OF THE INVENTION

Electronic components may be produced that comprise a) a substrate layer; b) an insulator layer coupled to the substrate layer, wherein the insulator layer comprises at least two different kinds of embedded passive components; and c) at least one additional layer coupled to the insulator layer.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 is a schematic diagram of a conventional layer structure comprising embedded passive components.

FIG. 2 is a schematic diagram of a preferred embodiment.

FIG. 3 is a flowchart showing a method of preparing a preferred embodiment.

FIG. 4 is a schematic diagram of a preferred embodiment.

### DETAILED DESCRIPTION

Electronic components, as contemplated herein, are generally thought to comprise any layered component that can be utilized in an electronic-based product. Contemplated electronic components comprise circuit boards, chip packaging, dielectric components of circuit boards, printed-wiring boards, and other components of circuit boards, such as capacitors, inductors, and resistors.

Electronic-based products can be “finished” in the sense that they are ready to be used in industry or by other consumers. Examples of finished consumer products are a television, a computer, a cell phone, a pager, a palm-type organizer, a portable radio, a car stereo, and a remote control. Also contemplated are “intermediate” products such as circuit boards, chip packaging, and keyboards that are potentially utilized in finished products.

Electronic products may also comprise a prototype component, at any stage of development from conceptual model to final scale-up mock-up. A prototype may or may not contain all of the actual components intended in a finished product, and a prototype may have some components that are constructed out of composite material in order to negate their initial effects on other components while being initially tested.

Electronic products and components may comprise layered materials, layered components, and components that are laminated in preparation for use in the component or product. Layers that include or comprise embedded passive components can make up the finished layered component or product.

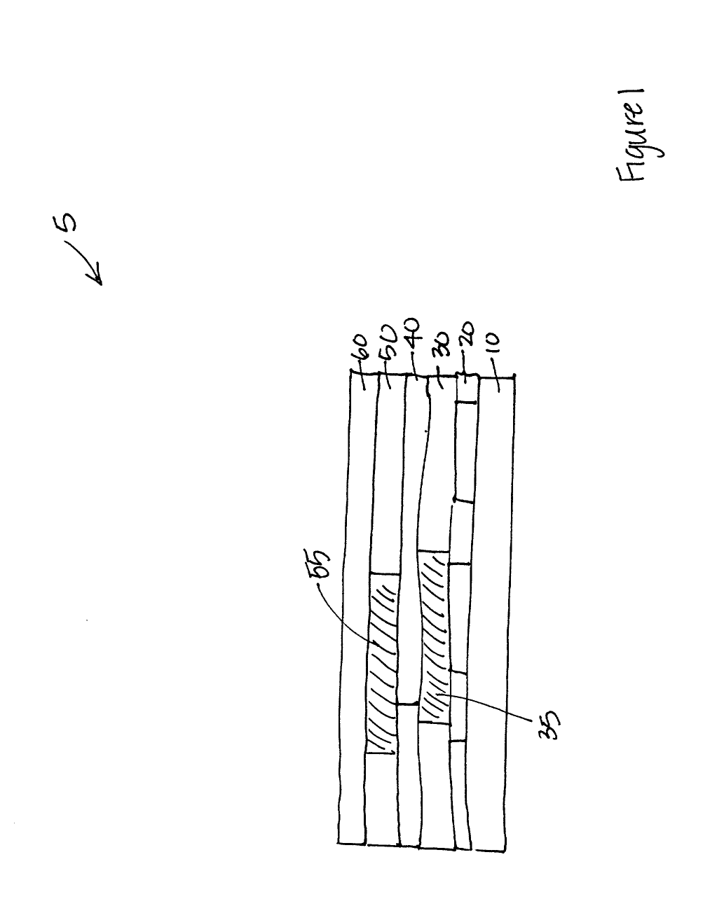

FIG. 1 shows a layered electronic component 5, such as a printed circuit board that comprises a conventional “lay up” of layers, wherein at least one of the layers has embedded passive components. The printed circuit board 5 generally comprises the following components: a) a substrate layer 10, b) a patterned metal layer 20, c) a dielectric material 30 comprising an embedded capacitor 35, d) a patterned metal layer 40, e) a dielectric material 50 that is either resistive or comprises an embedded resistor 55, and f) at least one additional layer 60.

A conventional substrate layer 10, as well as those substrates contemplated herein, generally comprises any desirable substantially solid material. However, in most layered components, the substrate layer 10 comprises a silicon-based material. The substrate layer 10 functions in a conventional component to provide support for the layered materials that are built up or “laid up” on the substrate layer 10. It may also function as a dielectric material or as a bonding point for layers below the substrate layer 10.

The patterned metal layers 20 and 40 function as electronic connectors between the layered components, and in some cases as impedance controllers. Each layer must be functionally connected in order for the electronic component to be efficient and operable. Generally, the metal layers 20 and 40 comprise any metal or conductive material that acts as a metal. The metal layers 20 and 40 usually comprise copper or nickel traces.

Conventional layers 30 and 50 that comprise embedded-type of components are generally thin resistive or dielectric films coated on copper foil and are supplied by a vendor as embedded passive component material. Problems that arise while using these types of materials are as follows: 1) these materials are difficult to process and to uniformly control the thickness of the layer, 2) the dielectric films are rarely imageable without applications of photoresist materials, and 3) resistors and capacitors cannot be formed on the same layer because of the physical, chemical and mechanical difference in the conventional materials previously discussed.

Additional layers 60 are added to the previous layers containing the resistors and capacitors in order to complete the circuit or protect the board. These additional layers will comprise materials such as metals, metal alloys, composite materials, polymers, monomers, organic compounds, inorganic compounds, organometallic compounds, resins, adhesives and optical wave-guide materials, depending on the needs of the customer and the component.

Although these conventional layered materials containing embedded resistors and capacitors have been functional, they are considered bulky, thicker, and harder to make and use than what is desirable for a scaled down component.

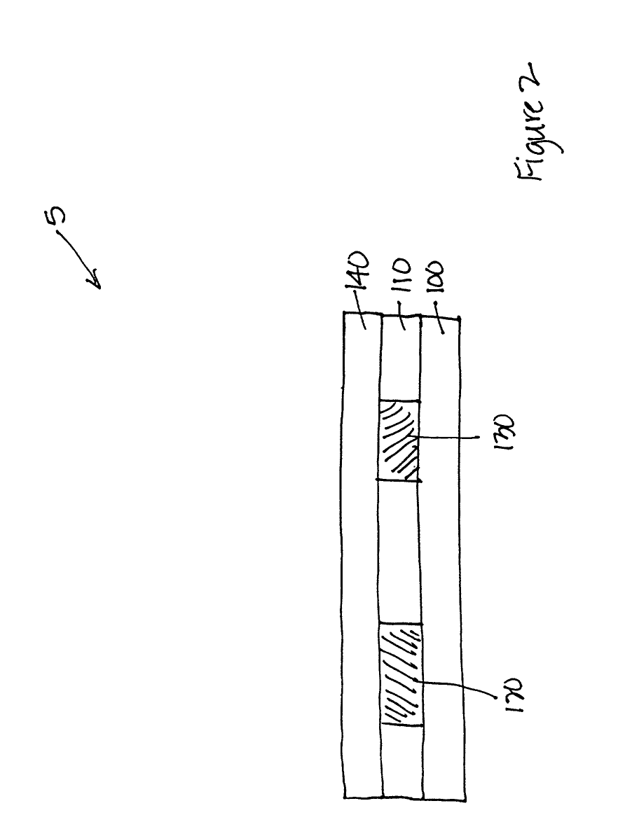

In FIG. 2, a layered electronic component 5 having embedded components within an insulator layer contemplated herein comprises a) a substrate layer 100; and b) an insulator layer 110 coupled to the substrate layer 100, wherein the insulator layer 110 comprises at least two different kinds of embedded passive components 120 and 130. In additional contemplated components, additional layers 140 may be added in order to continue to build the circuit, complete the circuit, or protect the circuit.

The substrate layer 100, as described earlier, may comprise any desirable substantially solid material. Particularly desirable substrate layers 100 would comprise films, glass, ceramic, plastic, metal or coated metal, or composite material. In preferred embodiments, the substrate 100 comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and it's oxides), a polymer-based packaging or board interface such as found in a polyimide-based flex package, lead or other metal alloy solder ball surface, glass and polymers such as polyimides, BT (triazine/bismalemide), and FR4. In more preferred embodiments, the substrate 100 comprises a material common in the packaging and circuit board industries such as silicon, copper, glass, and another polymer.

The substrate layer 100 may also comprise a plurality of voids if it is desirable for the material to be nanoporous instead of continuous. Voids are typically spherical, but may alternatively or additionally have any suitable shape, including tubular, lamellar, discoidal, or other shapes. It is also contemplated that voids may have any appropriate diameter. It is further contemplated that at least some of the voids may connect with adjacent voids to create a structure with a significant amount of connected or “open” porosity. The voids preferably have a mean diameter of less than 1 micrometer, and more preferably have a mean diameter of less than 100 nanometers, and still more preferably have a mean diameter of less than 10 nanometers. It is further contemplated that the voids may be uniformly or randomly dispersed within the substrate layer. In a preferred embodiment, the voids are uniformly dispersed within the substrate layer 100.

Substrate layers 100 contemplated herein may also comprise at least two layers of materials. One layer of material comprising the substrate layer 100 may include the substrate materials previously described. Other layers of material comprising the substrate layer 100 may include layers of metals, polymers, monomers, organic compounds, inorganic compounds, organometallic compounds, continuous layers and nanoporous layers. In preferred embodiments, the substrate layer 100 comprises a wafer, such as a silicon wafer, coupled with a metal trace or patterned metal layer. The metal trace is designed to electronically connect the substrate layer with other layers, as well as providing impedance control.

Suitable materials that can be used in additional substrate layers 100 comprise any material with properties appropriate for a printed circuit board or other electronic component, including pure metals, alloys, metal/metal composites, metal ceramic composites, metal polymer composites, cladding material, laminates, conductive polymers and monomers, as well as other metal composites.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, zinc, vanadium, aluminum, chromium, platinum, gold, silver, tungsten, molybdenum, cerium, promethium, and thorium. More preferred metals include titanium, silicon, copper, nickel, platinum, gold, silver and tungsten. Most preferred metals include titanium, silicon, copper and nickel. The term “metal” also includes alloys, metal/metal composites, metal ceramic composites, metal polymer composites, as well as other metal composites.

Contemplated polymers may also comprise a wide range of functional or structural moieties, including aromatic systems, and halogenated groups. Furthermore, appropriate polymers may have many configurations, including a homopolymer, and a heteropolymer. Moreover, alternative polymers may have various forms, such as linear, branched, super-branched, or three-dimensional. The molecular weight of contemplated polymers spans a wide range, typically between 400 Dalton and 400000 Dalton or more.

As used herein, the term “monomer” refers to any chemical compound that is capable of forming a covalent bond with itself or a chemically different compound in a repetitive manner. The repetitive bond formation between monomers may lead to a linear, branched, super-branched, or three-dimensional product. Furthermore, monomers may themselves comprise repetitive building blocks, and when polymerized the polymers formed from such monomers are then termed “blockpolymers”. Monomers may belong to various chemical classes of molecules including organic, organometallic or inorganic molecules. The molecular weight of monomers may vary greatly between about 40 Dalton and 20000 Dalton. However, especially when monomers comprise repetitive building blocks, monomers may have even higher molecular weights. Monomers may also include additional groups, such as groups used for crosslinking.

As used herein, the term “crosslinking” refers to a process in which at least two molecules, or two portions of a long molecule, are joined together by a chemical interaction. Such interactions may occur in many different ways including formation of a covalent bond, formation of hydrogen bonds, hydrophobic, hydrophilic, ionic or electrostatic interaction. Furthermore, molecular interaction may also be characterized by an at least temporary physical connection between a molecule and itself or between two or more molecules.

Thus, it is contemplated that the substrate layer 100 may comprise a single layer of conventional substrate material. It is alternatively contemplated that the substrate layer 100 may comprise several layers, along with the conventional substrate material, that function to build up part of layered electronic component 5.

Once the substrate layer 100 is designed and produced, an insulator layer 110 can be coupled to the substrate layer 100. The insulator layer 110 is designed to insulate, electronically and environmentally, any embedded components from other embedded components or surrounding layers, to withstand the environment, such as heat and humidity, and to act as an efficient resistor. The insulator layer generally comprises any suitable and desirable material depending on the needs of the customer and the design needs of the component. In preferred embodiments, the insulator comprises a resin-based material or thermosetting plastic that can be imaged and etched.

Passive components 120 and 130, such as resistors and capacitors, can be embedded into etched “compartments” in the insulator layer 110. The passive components 120 and 130 are generally in paste form, such that the etched compartments can be easily filled and the compartment space maximized. It is preferred that the passive components are comprised of different materials than those materials that make up the insulator layer 110. In other words, the insulator layer 110 comprises a material that acts as an effective resistor. It is preferred that the embedded resistor in the insulator layer 110 is not the same material as the insulator layer material 110. It is more preferred that the passive components 120 and 130 comprise two different kinds of materials that are also different from the insulator layer 110.

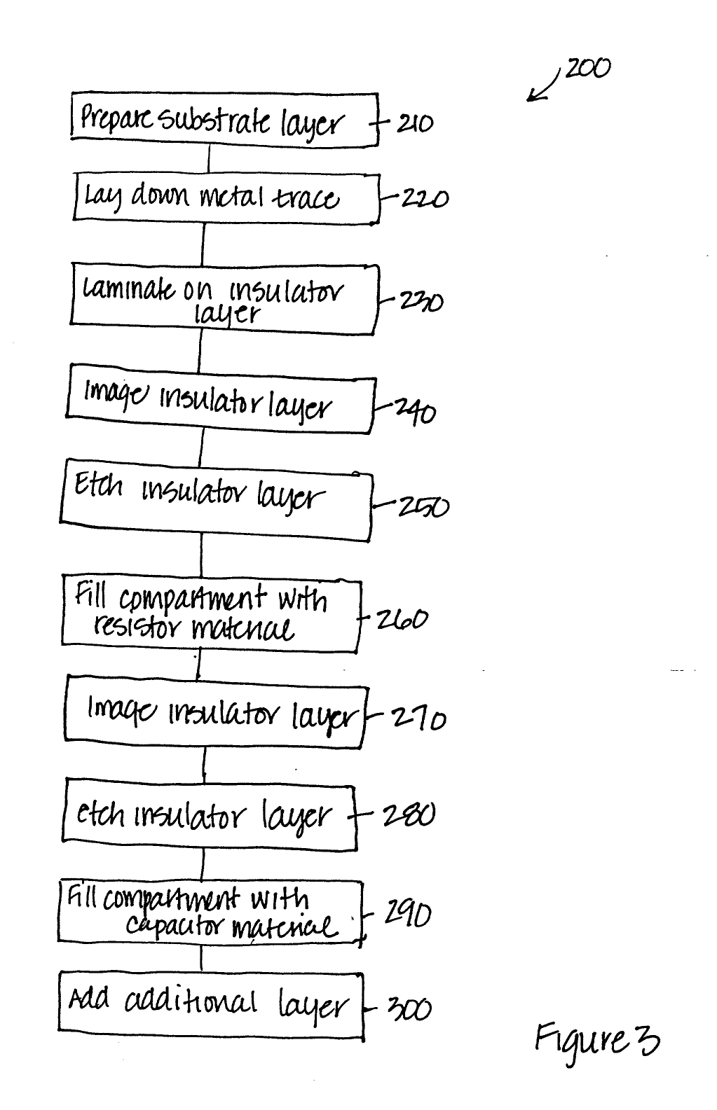

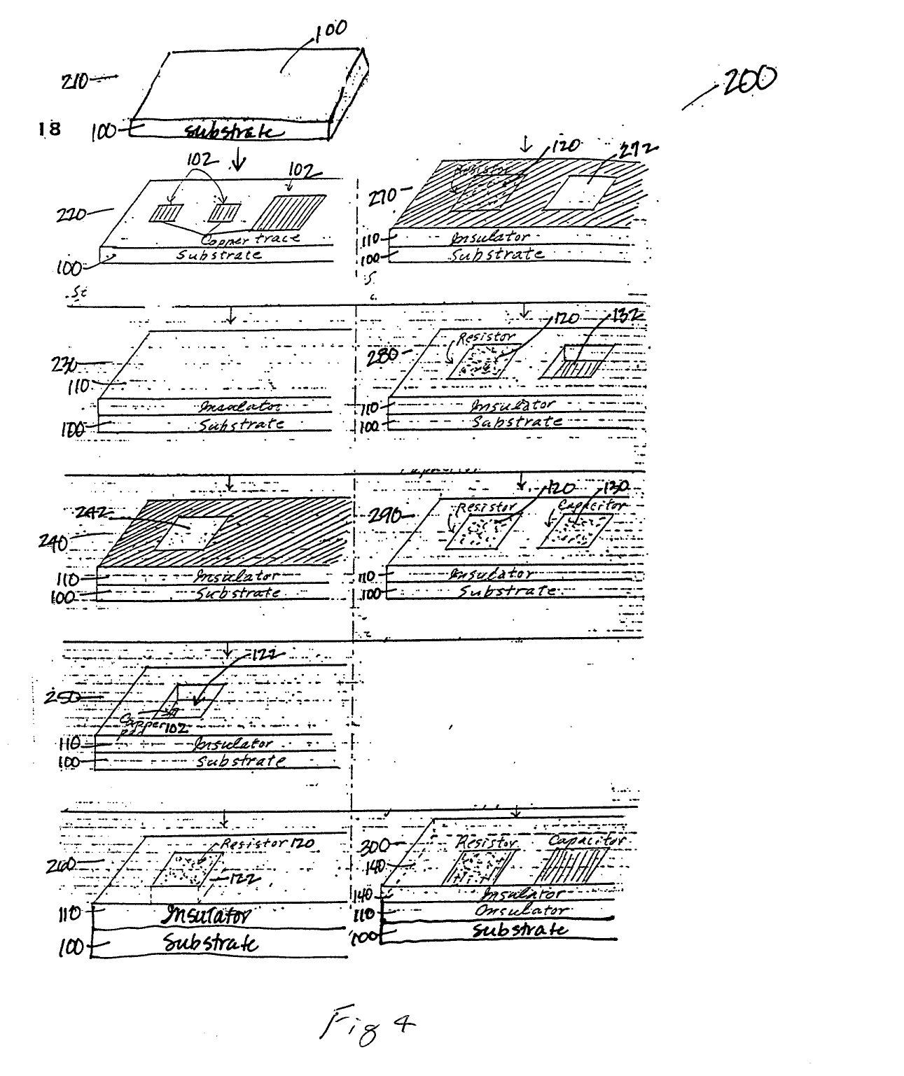

FIG. 3 shows a preferred method 200 of preparing the layered component comprising an insulator layer having embedded passive components of two different kinds of materials. A substrate layer 100 is prepared 210 that forms the basis for the component contemplated herein. A metal trace or patterned metal layer 102 is laid down 220 as part of the substrate layer 100. An insulator layer 110 is laminated 230 onto the substrate layer 100. The insulator layer is imaged 240 creating an etching pattern 242 for the resistor 120. The imaged insulator layer 110 is etched 250 to create a compartment 122 for the resistor 120 while exposing a portion of the metal layer 102 that had been previously laid down as part of the substrate layer 100. The compartment 122 is filled 260 with the resistor material or paste 124. The insulator layer 110 is further imaged 270 creating an etching pattern 272 for the capacitor 130. The imaged insulator layer 110 is etched 280 to create a compartment 132 for the capacitor 130 while exposing a portion of the metal layer 102 that had been previously laid down as part of the substrate layer 100. The compartment 132 is filled 290 with the capacitor material or paste 154. Additional layers can then be added 300 to the finished insulator layer 110. A graphical diagram of this preferred method and preferred embodiment of the subject matter described herein is shown by the detailed example in FIG. 4.

A layer of laminating material or cladding material can be coupled to the layered electronic component 5 depending on the specifications required by the component. Laminates are generally considered fiber-reinforced resin dielectric materials. Cladding materials are a subset of laminates that are produced when metals and other materials, such as copper, are incorporated into the laminates. (Harper, Charles A., Electronic Packaging and Interconnection Handbook, Second Edition, McGraw-Hill (New York), 1997.)

Additional layers of material 140 may be coupled to the insulator layer 110 in order to continue building a layered component or printed circuit board 5. It is contemplated that the additional layers 140 will comprise materials similar to those already described herein, including metals, metal alloys, composite materials, polymers, monomers, organic compounds, inorganic compounds, organometallic compounds, resins, adhesives and optical wave-guide materials.

Bonding materials may also be used to produce the layered component and may comprise any suitable adhesive, resin, laminate, bond-ply, polymer, monomer, or pre-preg material. It is contemplated that bonding materials can and will act as a dielectric material once the layered material 5 is cured. In contemplated embodiments, the bonding materials comprise FR4 epoxy, cyanate esters, polyimides, and glass reinforced compounds. In more preferred embodiments, the bonding materials comprise one of FR4 or cyanate ester.

Although several different materials and preferred combinations have been previously described for the components of the layered component 5, it should be realized that the composition of the layered component 5 is directly dependent on the needs of the customer, the component or the product. In order for the vendor of the layered component 5 to gauge the needs of the customer, the component and/or the product, the vendor must have a method of receiving as much information from the customer as possible.

Thus, specific embodiments and applications of electronic components comprising insulator layers having embedded passive components have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. An electronic component, comprising:
a substrate layer; and
an insulator layer coupled to the substrate layer, wherein the insulator layer comprises at least two different kinds of embedded passive components.

2. The electronic component of claim 1, further comprising at least one additional layer coupled to the insulator layer.

3. The electronic component of claim 2, wherein the at least one additional layer comprises at least one of a metal, a polymer, an inorganic compound, a monomer, an organometallic compound and a metal alloy.

4. The electronic component of claim 1, wherein the electronic component is a printed circuit board.

5. The electronic component of claim 1, wherein the substrate layer comprises at least one layer.

6. The electronic component of claim 5, wherein the substrate layer comprises a silicon wafer.

7. The electronic component of claim 6, wherein the substrate layer further comprises a layer of conductive material.

8. The electronic component of claim 7, wherein the layer of conductive material comprises copper or nickel.

9. The electronic component of claim 1, wherein the insulator layer is coupled to the substrate layer by a laminating material.

10. The electronic component of claim 1, wherein the insulator layer comprises at least one of a polycarbonate, a fused silica compound and an alumina compound.

11. The electronic component of claim 1, wherein the at least two embedded passive components comprises a resistor and a capacitor.

12. An electronic product comprising the electronic component of claim 1.

13. A method of producing a layer having at least two different kinds of embedded passive components, comprising
imaging an insulator layer to create a first pattern on the insulator layer;
etching the first pattern on the insulator layer to create a first compartment in the insulator layer;
filling the first compartment with a first material to form a first passive component;
imaging the insulator layer to create a second pattern on the insulator layer;
etching the second pattern on the insulator layer to create a second compartment in the insulator layer; and
filling the second compartment with a second material to form a second passive component.

14. The method of claim 13, wherein the first and second passive components are different components.

15. The method of claim 13, wherein the first passive component is a resistor and the second passive component is a capacitor.

16. The method of claim 13, wherein the passive components comprise a resistor paste and a capacitor paste.

17. The method of claim 13, wherein coupling at least one additional layer comprises coupling a laminating material.
